(19) United States
(12) Patent Application Publication
(10) Pub. No.: US 2004/0253824 A1
(43) Pub. Date: Dec. 16, 2004

(54) Arrangement for monitoring a thickness of a layer depositing on a sidewall of a processing chamber

(76) Inventor: Volker Tegeder, Dresden (DE)

Correspondence Address: SLATER & MATSIL, L.L.P., 17950 PRESTON RD, SUITE 1000, DALLAS, TX, 75252-5793, US

(21) Appl. No.: 10/861,902

(22) Filed: Jun. 4, 2004

Related U.S. Application Data
(63) Continuation of application No. PCT/EP02/13102, filed on Nov. 21, 2002.

(30) Foreign Application Priority Data
Dec. 7, 2001 (EP) 01129129.1

(51) Int. Cl. B05D 1/00; H01L 21/311; H05H 1/00

(52) U.S. Cl. 438/696

(57) ABSTRACT

A light source (1) emits a light beam (6) into a plasma chamber (5) onto a sensor (2), which provides a measurement of the thickness of a film layer depositing on its surface (58) by means of a reflection or re-emission of light through the depositing layer (10) back on a detector (3), which is preferably mounted outside the plasma chamber (5). The arrangement allows an online measurement of the growing thickness of the depositing layer (10) during, e.g., plasma CVD- or plasma etching processes in semiconductor manufacturing. Providing a mirror layer (53) with sensor (2) the reflected light intensity can be compared with the incident light beam (6) intensity leading to a thickness determination by means of known absorption or interference curves.

### CROSS-REFERENCE TO RELATED APPLICATIONS

This application is a continuation of co-pending International Application No. PCT/EP02/013102, filed Nov. 21, 2002, which designated the United States and was published in English, and which is based on European Application No. 01129129.1, filed Dec. 7, 2001, both of which applications are incorporated herein by reference.

### TECHNICAL FIELD

The present invention relates to an arrangement for monitoring a thickness of a layer depositing on a sidewall of a processing chamber.

### BACKGROUND

In semiconductor device manufacturing many processing steps involve a removal or deposition of layer material on the surfaces of the semiconductor devices in a processing chamber.

Examples are the processing steps of plasma etching or plasma chemical vapor deposition (PCVD). While performing such processing steps, it often occurs unintentionally that reaction products or polymer material physically removed from the device surface deposit on the sidewalls of the processing chamber. In the case of plasma etching, e.g., reactive ion etching (RIE), reactive ion beam etching (RIBE) or chemically assisted reactive ion beam etching (CAIBE), hot reaction products may condense in a low-pressure environment on the comparatively cold plasma chamber sidewalls. Etching is also often performed on semiconductor devices being covered with a resist mask on its surface comprising a polymer composition leading to a deposition of polymer layers on the sidewalls.

With continuing utilization of the processing chamber, the thickness of the deposited layer grows, and when a characteristic thickness value depending on the layer composition is exceeded, a process called flaking occurs within this layer.

The relatively smooth surface structure hitherto existing on the growing layer breaks up leading to a rough surface structure. Occasionally, pieces of this layer lose support, split off, and may disadvantageously fall and stick onto the device surface, which is currently being manufactured. In the case of a semiconductor wafer, parts of integrated circuits might be destroyed. In order to anticipate flaking events, one typically performs wet cleaning or other cleaning steps on that processing chamber, during which unfortunately, production has to be discontinued.

The exact choice of time for starting the cleaning step generally depends on operation experience. Typically, a wet clean is performed, and by investigating e.g., consumable parts removed from the processing chamber, the layer thickness of e.g., polymers, deposited on the part can be inspected by means of dedicated measurement tools. Also, the surface structure can be investigated to determine a posteriori, whether there would have been sufficient time to continue production before cleaning the sidewalls, or whether it is already too late, i.e., flaking has already started. Another approach is to perform particle tests or statistics on test production devices. In any case, a loss in production efficiency is involved when performing cleaning steps of processing chambers just be experience and/or exterior measurements.

It has also been proposed to measure deposition thicknesses by means of heat capacity or ultrasonic wave runtime measurements. While these approaches provide in-situ and online measurements, the corresponding measurement arrangements are complicated due to the necessity of leading electrical conductors through wall openings in the sidewall of the processing chamber. Moreover, runtime measurements are sensitive to temperature changes, and are also prone to being affected by irritating reflections due to the consumable parts inside the processing chamber.

In WO 01/00900 A1 an arrangement for monitoring the change of deposition layer thicknesses in processing chambers is provided. This arrangement uses a sensor having a transparent or at least semi-transparent orifices, through which a light beam originating from a light source is transmitted to a detector for measuring the light intensity. The sensor is placed inside the processing chamber and is prone to layer deposition. The intensity of light traversing the orifice decreases due to absorption of the layer growing on and inside the orifice.

U.S. Pat. No. 6,025,916 discloses an arrangement for measuring for a polymer build-up on plasma chamber sidewalls. It comprises a light source, a window mounted within the sidewall and a detector, the window having a surface oriented off the sidewall towards the inner space of the plasma chamber. A layer deposition on the inner space surface of the window is monitored by measuring interferences of light beams being reflected by a surface of the depositing layer and by said inner surface, which contacts the depositing layer.

### SUMMARY OF THE INVENTION

In one aspect, the present invention provides an arrangement and a method for monitoring the thickness of a layer depositing on sidewalls of processing chambers, which enhances the productive time between two adjacent wet clean steps while retaining or increasing the manufacturing quality of a processing chamber with least effort spent in costs and material.

Moreover, a preferred arrangement enables the use of existing etching or deposition tools together with the present arrangement, thereby reducing the necessity of adapting the chamber construction to the arrangement requirements, in particular the number, size and position of chamber windows.

The preferred embodiment provides an arrangement for monitoring a thickness of an absorbing layer deposited on a sidewall of a processing chamber. At least a first light source directs a light beam onto a surface of a sensor. The sensor has the surface designed to affect the intensity of light, which it emits in response to the light beam, and is covered with an absorbing layer. A detector measures an intensity of light emitted from the sensor. A control unit is connected to the detector and determines the thickness of the absorbing layer deposited on the sidewall from the intensity measurement. In the preferred embodiment, the sensor is placed inside the plasma chamber and is mounted on the sidewall. The light source is arranged to direct the light beam towards the surface thereby traversing an inner space of the plasma chamber and the absorbing layer. The sensor includes at least one of: a) a layer comprising fluorescence material; or b) a mirror layer for reflecting the incident light beam.

Using a method for monitoring a layer deposition on a sidewall of a plasma chamber utilizing such an arrangement, a light beam is irradiated onto the sensor surface using the light source. The intensity of light being emitted or reflected by the surface using the detector is measured. The value of measured intensity is compared with a threshold value representing a critical thickness value of a layer on the sidewall using the control unit and a signal is issued in response to that comparison.

In particular, the measured intensity is interpreted in terms of absorption, which is related to the layer thickness. In another embodiment, the intensity is interpreted in terms of interference of light reflected from the mirror surface and that reflected from the surface of the layer deposited on the sensor mirror surface, which is also related to the actual thickness of the layer.

The thickness of a depositing film layer on a processing chamber sidewall is determined by a transmission or reflectivity measurement of a light beam through the corresponding film layer depositing on a sensor. The sensor preferably is placed in the local vicinity of the sidewall to be inspected inside the processing chamber. By means of a light beam, the light source has an access path to that sensor. The sensor either directly reflects the light by means of a mirror layer, which may be the surface or any underlying layer, or receives the light beam, converts it followed by re-emitting the light into one or more directions.

The light source can be a laser or any other multi-wavelength light source. It is also possible that the multi-wavelength can be changed online by means of optical filters or similar means. The optical light path from the light source to the sensor may comprise mirrors for redirecting the light towards the sensor. The light source is placed preferably outside the processing chamber and has access to the sensor through a window.

A placement inside the processing chamber is particularly possible in the advantageous case of the processing chamber being a plasma chamber and the plasma light serving as the light source so that there is generally no restriction of the light source placement according to the present invention.

The film layer growing on the sensor surface by means of absorption has the effect of absorbing light intensity before the light beam intersects the sensor surface. After reflection or re-emitting the light, the amount of intensity is once more absorbed by the film layer. In the case of reflection from a mirror layer of the sensor, the angle of incidence of the incident light beam and the exiting angle of the exiting light beam are typically the same, thereby defining the relative placement of light source, sensor and detector. There is also a direct optical path between the sensor and the detector, which may also comprise redirecting mirrors. Preferably, the detectors are mounted outside the processing chamber, but a placement inside is not excluded.

One advantage of the preferred embodiment of the present invention is that a relation between layer thickness and light intensity can be established either theoretically or by experiments. This relationship can then serve as the basis for online thickness measurements.

A control unit is connected to the detector in order to determine the actual thickness of the deposited film layer from the light intensity measurement. Preferably by means of previous experiments, the thickness of the sidewall layer can be derived by the control unit from the determined thickness of the deposited film layer on the sensor. This is because the deposition rate can vary considerably inside the processing chamber from position to position and from surface material structure to a next. Thus, gauging can be performed by measuring and comparing layer thicknesses on the sensor substrate and the sidewall after an amount of utilization time of the processing chamber. Preferably, this procedure is repeated for a set of utilization times in order to regard a nonlinear relation.

The detector can be any photosensitive device that is able to receive and detect optical wavelength as well as infrared light or ultraviolet light. It is considered that it comprises optical means for providing a position-dependent resolution, i.e., a picture of the sensor surface in order to detect gradients of film layer depositions. This may be provided by a CCD-camera or a photo diode.

If, for example, a sensor surface is free of a deposited layer, i.e., at an initial state or after having experienced a cleaning step, the intensity of reflected or re-emitted light is substantially equal to the incident beam intensity. Then the intensity of the re-emitted or reflected light decreases monotonically with growing layer thickness until flaking starts. Thus, online measurement of light intensity using the detector provides a means for determining the amount of time that can be used to continue semiconductor device processing using the common processing chamber set-up. When such a time event is reached, i.e., flaking starts, in this example defining the minimum light intensity point, a sudden light intensity change occurs indicating that flaking has already started. Using the control unit, this time event can be predetermined. A signal can be issued either indicating the time left for processing, or warning the operator to start the onset of a cleaning step, i.e., wet clean.

To accomplish this, an exact measurement of intensity as a function of layer thickness can be carried out at the time of tool setup, e.g., such that when an actual measurement is made according to the present invention, the experience obtained from the previous setup-measurements can be used to determine the actual status.

What can actually be measured is a light intensity decrease due to absorption of the depositing film layer or interference of light reflected by the sensor mirror—layer interface and by the layer surface. The difference of the reflected light beam and the re-emitted light derives from two distinct preferred embodiments.

The first is reflection due to a mirror layer that is separated from the sensor surface by means of a transparent layer protecting the mirror layer from the reactant gases in e.g., the plasma chamber. Thus, the light beam traverses the deposited film layer and the protection layer, and is then reflected by the mirror layer, which for example can be composed of a metal deposited on a silicon layer or the silicon layer itself. Afterwards, it traverses once more each the protection layer and the deposited film layer before it reaches the detector.

The second aspect of re-emission considers the light beam to activate a fluorescence layer beneath, e.g., the protection layer at a first wavelength, while the fluorescence layer re-emits light at a second wavelength. This feature can be utilized in that the wavelength of the incident light beam is chosen such that it is not absorbed significantly by the deposited film layer, and the intensity is chosen such as to reach the saturation regime of the fluorescence layer, thereby being independent from the actual intensity losses of the incident beam before it reaches the fluorescence layer. Thus, with a range of not-too-high thickness values of the deposited film layer, it can be assumed that the fluorescence layer emits light with constant intensity, which is then absorbed when traversing the deposited film layer from beneath. Generally, the re-emitted light from the fluorescence layer has diffuse directions leading to a weaker signal in the detector. The fluorescence material is chosen such that the re-emitted light wavelength experiences significant absorption due to the deposited film layer in contrast to the incident beam.

The re-emitted light, or the reflected light, having a spectral distribution provides a further feature that a detector supplied with a spectral analysis means can additionally provide information about the depositing film layer chemical composition as well as physical information like temperature, or partical sizes, roughness. In this case, the detector is embodied as a spectrometer.

### BRIEF DESCRIPTION OF THE DRAWINGS

The invention will be better understood by reference to embodiments taken in conjunction with the accompanying figures wherein:

FIG. 1 shows an embodiment of the present invention with a laser beam directed upon a sensor inside a plasma etching chamber and a detector monitoring the intensity of reflected light with time;

FIG. 2 shows an embodiment of the invention with two sensors placed at different positions inside the plasma chamber;

FIG. 3 shows an embodiment of the invention, where the sensor can be moved along a guide rail in the chamber, and a mirror is rotated redirecting the laser beam onto the sensor;

FIG. 4 shows an embodiment of the sensor having a mirror layer for reflecting an incident light beam;

FIG. 5 shows an embodiment of the sensor having a fluorescent layer;

FIG. 6 shows an embodiment of the present invention with chopping the light beam under control of the control unit connected to the detector;

FIG. 7 shows an embodiment with a movable aperture; and

FIG. 8 shows an embodiment of the sensor having four surface structures with different sensitivities to layer deposition.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

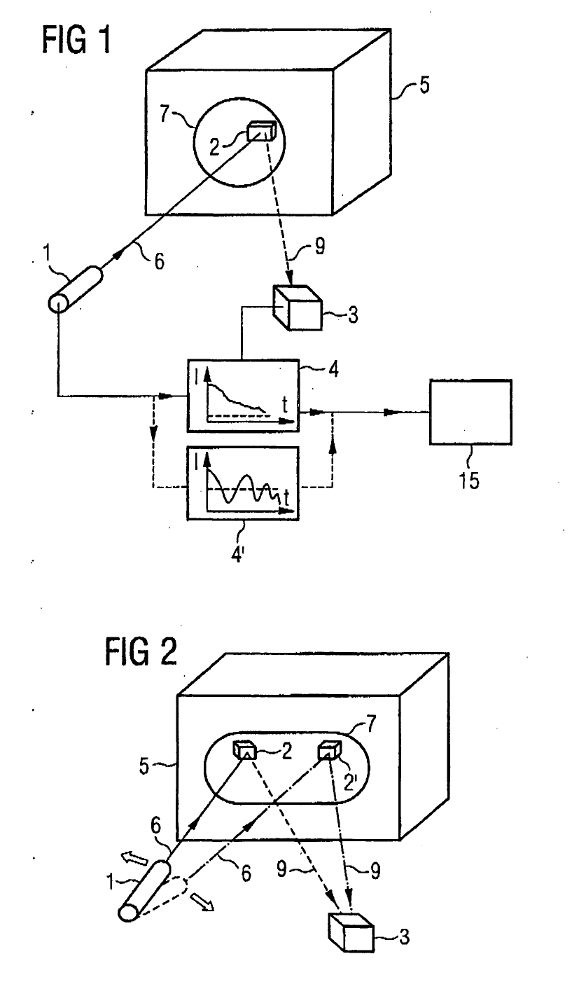

FIG. 1 shows an arrangement that includes a laser 1 emitting a light beam 6 through a window 7 of plasma chamber 5 onto a sensor 2. The plasma chamber 5 used in this embodiment is intended for etching semiconductor wafers. With ongoing use of the plasma chamber, i.e., etching, a film comprising e.g., polymers, deposits on the sensor 2 surface. Before, during, or after etching—whenever the light beam is incident on that sensor 2—the light beam 6 traverses the film layer 10 (see FIG. 4) and is reflected by an underlying mirror layer (see, e.g., element 53 in FIG. 4). Once more, the light beam traverses the film layer 10 and exits the plasma chamber 5 through the same window 7 and is collected by a detector 3. A control unit 4 is connected to the detector 3 and calculates the intensity from the detection signal. Control unit 4 is also connected to the laser light source 1 for having a reference intensity with which the detected intensity can be compared.

A threshold value for intensity as inferred from prior experiment is available, with which the current intensity being measured can be compared—after normalizing it with the reference intensity. Due to absorption of the adsorbing material, the intensity of the reflected light generally decreases such that the intensity curve as plotted versus time intersects with the constant threshold value line. In response to this event, the comparison results in a signal that is issued by the system, e.g., the control unit 4, which is then forwarded to, e.g., the line control system or the manufacturing execution system warning or informing the operator that a step of wet clean is due.

In a refined embodiment, the control unit 4 calculates from the slope of the measured intensity as a function of time a time value, where the intersection of the measured curve with the threshold value presumably will occur. This option provides operators more freedom when scheduling and planning forthcoming production.

As can also be seen from FIG. 1, an alternatively working control unit 4 interprets the measured intensity as a function of time in terms of interference. With increasing layer thickness, the light amplitudes reflected each from the layer surface and the mirror—deposited layer interface are added or subtracted to each other depending on their sign and depending on the wavelength of the incident light due to the different light path lengths. In this case, the intensity curve does not monotonically decrease, rather several maxima and minima can be recognized. The number of maxima or minima already run through in the present process setup show the current status. A threshold value, which is found by experience, can be given, and, e.g., an n-th crossover over a maximum or a threshold value indicates a critical layer thickness for the due onset of flaking and the necessary start of a wet clean step.

Preferably, monochromatic light is used for this embodiment. With this embodiment a time value for which the onset will occur in the future can as well be calculated.

Another embodiment of the arrangement according to the present invention is shown in FIG. 2. The laser 1 is movable in the sense that two different sensors 2 and 2′ mounted inside the plasma chamber 5 can be supplied with a light beam 6, which is arranged such that the reflected light beam meets the detector 3. In case of the reflection type of the present invention, the requirement that incidence angle and exerting angle of the preferably plain sensor surface is regarded. The feature of moveability of the light source 1 can be replaced by a movable mirror (not shown in FIG. 2) redirecting the light beam 6 onto the two sensors 2 and 2′ through the plasma chamber window 7.

Three aspects can be covered when employing two or more sensors: A first of the two sensors 2 (or 2′) is used for measuring the deposition layer 10 thickness, and thus is placed at a position inside the plasma chamber 5 suffering significantly from film deposition, while the second sensor 2′ (or 2) serves as a reference sensor providing a reference intensity, and therefore is placed at a position inside the plasma chamber 5 being substantially free of film layer deposition. The light source 1 supplies both sensors 2 and 2′ alternately with the light beam 6 and the detector 3 and/or the control unit 4 not shown in this figure perform the intensity normalization.

Both sensors 2, 2′ are mounted at different places for monitoring a spatial distribution of layer deposition inside the plasma chamber 5. Alternatively, or in addition, both sensors 2 and 2′ are arranged to provide different sensitivities for providing a thickness measurement covering different ranges of layer deposition strength. For example, if the deposition layer 10 becomes nearly opaque on the surface of sensor 2, the second sensor 2′, which provides a less efficient layer deposition, still allows some amount of transparence, and therefore enables an advanced thickness measurement on this sensor. The sensitivity may also be controlled either by heating/cooling or by providing a dedicated surface structure, e.g., roughness due to holes.

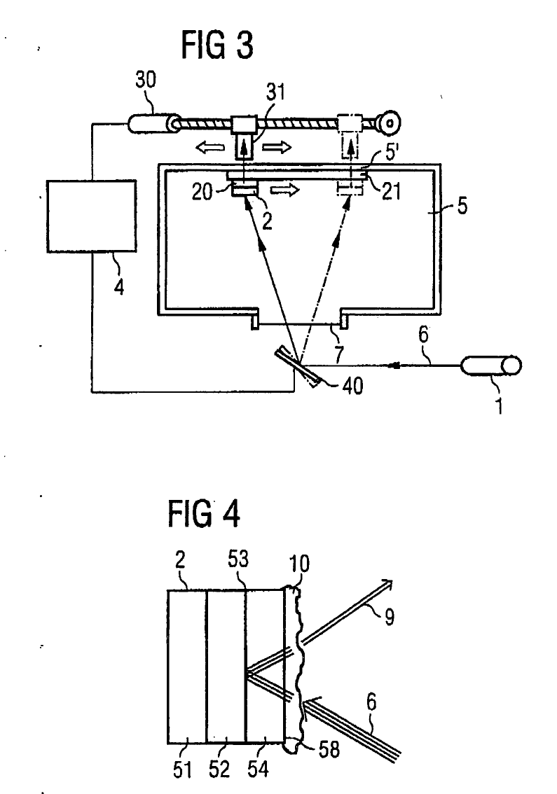

In a further embodiment shown in FIG. 3, at least one sensor 2 inside the plasma chamber 5 is supplied with a magnetic means 20 mounted on a guide rail 21 along which it can be moved. That guide rail 21 is mounted at the plasma chamber wall 5′. Behind this plasma chamber wall 5′ a motor 30 provides a movement of an exterial magnet 31 being magnetically coupled with the sensor magnet 20. Moving the exterior magnet 31, the sensor 2 is also moved and can be transferred to a position of interest in the plasma chamber 5.

The motor 30 is connected to the control unit 4, to which is also connected a rotatable mirror 40 for redirecting the laser beam 6 from the light source 1. By means of control unit 4, the movement of sensor 2 due motor 30 and the rotation of the rotatable mirror 40 can be synchronized in order to retain the beam on this servers area of sensor 2. A dedicated orientation mechanism of the sensor surface in order to supply the detector 3 not shown in FIG. 3 for clarity with emitted light 9 has also to be provided, then.

Using the embodiment shown in FIG. 3, special distribution of film layer 10 deposition can be monitored and problems easily recognized. For impeding problems of film layer deposition on the window 7, that window is embodied as a recess window.

A sensor element 2 of the reflection type is shown in FIG. 4. The surface 58 of a transparent protection layer 54 comprising SiO₂ surface as the base for the slowly growing film deposition layer 10. The protection layer 54 has a contact surface with a non-transparent base layer 52 made of silicon, which serves as a mirror layer reflecting the incident beam traversing the film layer 10 and the SiO₂ layer, and is manufactured by metal deposition on the silicon surface. Such a sandwich sensor 2 can be controlled in its sensitivity by a means for cooling/heating 51 layer. In the case of a cooling layer 51, a material working by means of the Peltier-effect is provided to increase the condensation of depositing material on the surface 58. Electrically heating layer 51 on the other hand, would decrease the amount of deposition per time.

In another refined embodiment, sensor 2 comprises a set of structures on surface 58, to which can be applied different temperatures, e.g., a temperature gradient. The detector 3 is then enabled to screen such a gradient, which possibly emerges in different layer deposition strengths depending on the temperature. Such characteristics can be measured.

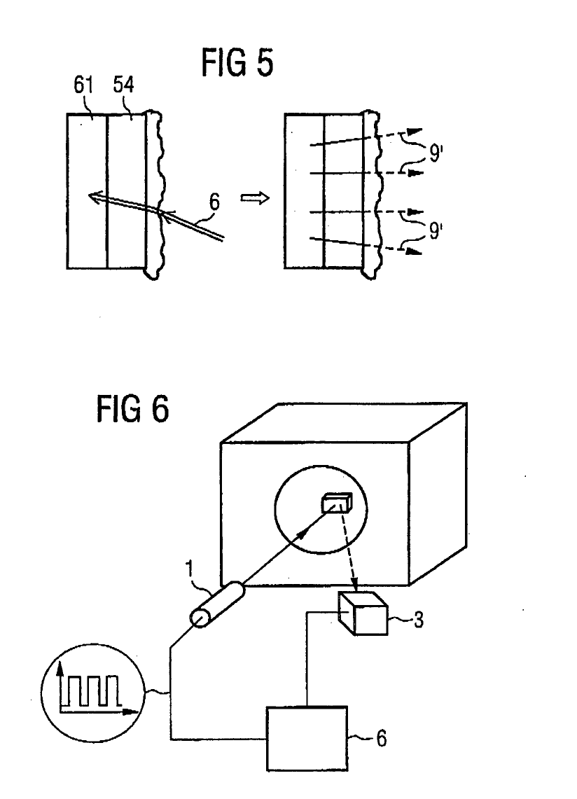

Another embodiment of the sensor 2 according to the present invention, is of the fluorescence type. As displayed in FIG. 5, the protection layer 54 covers a fluorescence layer 61, which is activated by light having adequate wavelength. The light beam intensity is strong enough to supply the fluorescence layer with a sufficient dose, such that light is re-emitted in the saturation regime of the fluorescence layer 61. Since in this case the re-emission intensity is known, the measurement of a reference intensity is not further needed. The fluorescence layer 61 then re-emits diffuse light 9′, which is then collected by the detector 3. What is measured here is the intensity loss during just one traversal through the film layer 10.

In order to increase this signal-to-noise ratio, the signal of the light source 1 can be troppered, which is synchronized with the light detection in detector 3. Correspondingly, control unit 4 performs the task of synchronizing light source 1 and detector 3, which is shown in FIG. 6.

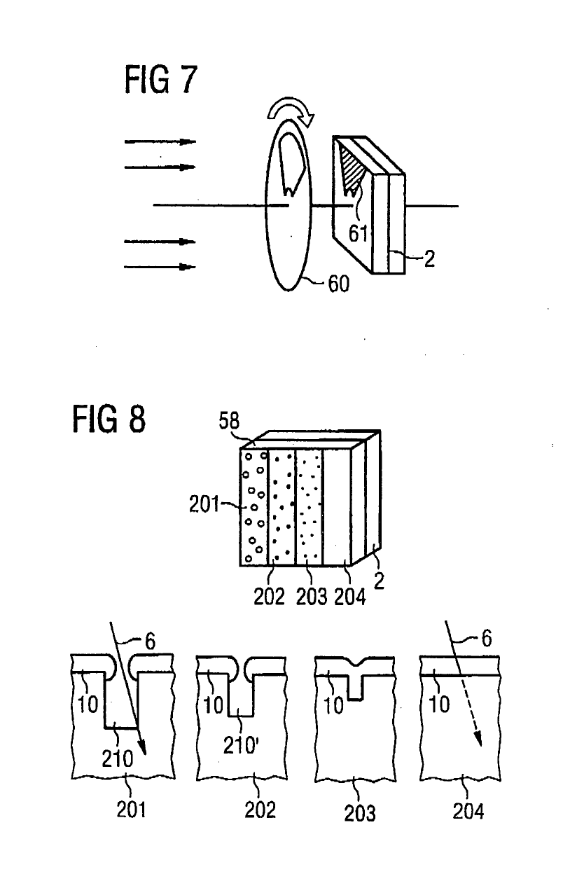

According to another embodiment, the sensor 2 is provided with a movable aperture 60, due to which a surface portion 61 of the sensor 2 is exposed to gases and material inside the plasma chamber 5. As indicated in FIG. 7, a rotatable plate having an aperture is positioned in front of the surface 58 of sensor 2 being sufficiently near to the surface such as to protect the non-exposed surface areas of sensor 2. In FIG. 7, the distance is not shown to scale, rather it should be near enough such that no contact with the surface is established yet.

Another embodiment of a sensor 2 is shown in FIG. 8. The sensor surface 58 comprises four different surface structures 201 to 204 each being supplied with holes or orifices of distinct size, depending on the area. For example, surface structure 201 having a dense grid of holes having the largest size provides a surface that is least sensitive to film layer deposition, because—as shown in the bottom section of FIG. 8—a larger orifice 210 needs an amount of time to be closed by the growing thickness of the deposition layer 10, which is larger than the time needed for the smaller orifices 210′ of surface structure 202. Surface structure 204 comprises no or negligible holes, and therefore, permits less amount of light to pass through the height range of the deposition layer 10, while the larger orifices allow more light to pass through. It is also possible to distribute a set of different sensors 2, 2′ inside the plasma chamber 5 each having their own roughness or density of holes in the surface 58 of sensor 2.

It is also possible to construct a pattern on the sensor surface that is extremely insensitive to film layer deposition, and thus can solve as a reference sensor for a light beam. In comparison of two or more sensor surfaces having different sensitivities can then be made inside the chamber 5.

It has to be noted that the sensor surface 58 can be any material compatible with plasma processors. In the case of a protection layer, which is transparent or in the case of a reflecting mirror layer 53, these requirements should hold in order to impede the change of transmission or absorption characteristics of the surface.

In another embodiment a light detector is mounted inside the chamber integrated into the surface of the sensor to measure the intensity of the light.

What is claimed is:

1. An arrangement for monitoring thickness of an absorbing layer deposited on a sidewall of a processing chamber, the arrangement comprising:
a sensor located adjacent a sidewall of a plasma chamber, the sensor having a surface being designed to affect the intensity of light that it emits in response to an impinging light beam, the sensor comprising at least one of a layer comprising fluorescence material or a mirror layer for reflecting an incident light beam;
at least a first light source arranged for directing a light beam onto the surface of the sensor, the light beam traversing an inner space of the plasma chamber;
a detector located to receive light emitted by the sensor; and
a control unit being functionally coupled to the detector, the control unit operable to determine a thickness of an absorbing layer deposited on the sidewall of the processing chamber.

2. The arrangement of claim 1 where the sensor comprises a layer of fluorescence material, wherein the light beam emitted by the light source comprises a first wavelength, for which the layer deposition material is substantially transparent, and wherein the light being re-emitted by the fluorescence material comprises a second wavelength, for which the deposition material absorbs intensity.

3. The arrangement of claim 1 wherein the detector is positioned outside the inner space, and wherein the processing chamber comprises a window through which the light beam can exit the processing chamber towards the detector.

4. The arrangement of claim 1 wherein the detector is positioned inside said inner space.

5. The arrangement of claim 1 wherein the sensor comprises a protection layer at its surface in order to not be affected by the deposition processing, the protection layer being transparent for light emitted by the light source.

6. The arrangement of claim 5 wherein the protection layer comprises silicon dioxide.

7. The arrangement of claim 1 wherein the sensor comprises a mirror layer and wherein the mirror layer comprises silicon and/or a metal.

8. The arrangement of claim 1 and further comprising a heater located near the sensor.

9. The arrangement of claim 1 and further comprising a cooling unit located near the sensor.

10. The arrangement of claim 9 wherein the cooling unit comprises a Peltier element.

11. The arrangement of claim 1 and further comprising a second light source arranged for directing light onto the surface of the sensor, the second light source having a different wavelength than the first light source.

12. The arrangement of claim 1 and further comprising a mirror located to redirect the light beam emitted from at least the first light source for scanning the sensor.

13. The arrangement of claim 1 wherein the first light source comprises a plasma light generated by a plasma inside the processing chamber.

14. The arrangement of claim 1 and further comprising a movable shutter for providing a variable aperture for a deposition process on the sensor surface.

15. The arrangement of claim 1 wherein the control unit is functionally coupled to the first light source and to the detector, the arrangement further comprising a chopping mechanism adjacent to the first light source for chopping the light beam.

16. The arrangement of claim 1 and further comprising a second sensor mounted inside the processing chamber.

17. The arrangement of claim 1 and further comprising a moving means for providing a movement of the sensor inside the processing chamber.

18. The arrangement of claim 17 wherein the moving means acts on the sensor by means of magnetic attraction, and wherein the moving means is located outside the processing chamber.

19. The arrangement of claim 1 wherein the sensor comprises at least two surface structures, a first surface structure having a first adsorption sensitivity and a second surface structure having a second adsorption sensitivity.

20. The arrangement of claim 19 wherein said adsorption sensitivity of each of the at least two surface structures is provided each by a multiple of holes representing a surface roughness supplied with the sensor surface.

21. The arrangement of claim 19 wherein the adsorption sensitivity of each of the at least two surface structures is provided by a surface temperature as supplied by a heater or a cooler.

22. The arrangement of claim 21 wherein the detector is a CCD-camera or one of a multiple of photo diodes.

23. The arrangement of claim 1 wherein the processing chamber is a plasma chamber.

24. A method for monitoring a layer deposition on a wall of a plasma chamber, the method comprising:
irradiating a light beam onto a sensor surface, the sensor being located adjacent a wall of a plasma chamber;
measuring intensity of light being emitted or reflected by the sensor surface, comparing a value of measured intensity with a threshold value representing a thickness value of a layer on the wall; and
issuing a signal in response to said comparison.

25. The method of claim 24 and further comprising:
irradiating a light beam onto a second sensor surface as a reference; and
measuring intensity of light emitted or reflected from said second sensor surface, wherein the threshold value is based upon the measured intensity of light from the second sensor surface.

26. The method of claim 24 wherein the method comprises comparing the value of measured intensity with a second measured value of light intensity, the second measured value being based upon a measurement of light emitted or reflected from a second sensor surface.

27. The method of claim 24 wherein measuring intensity comprises measuring the intensity of the light at different wavelengths to obtain a spectral distribution of reflected or emitted light.

28. The method of claim 24 and further comprising moving a mirror to redirect the beam of light in response to a movement of the sensor.

29. The method of claim 24 and further comprising calculating a time duration of a plasma chamber cleaning interval in response to said signal.

30. The method of claim 24 wherein the threshold value represents a thickness value that is obtained from multiple absorption measurements of the sensor being covered with different layer thicknesses, the absorption being related to the thickness of the layer.

31. The method of claim 24 wherein the threshold value represents a thickness value that is obtained from a multiple of interference measurements of different layer thicknesses covering the sensor, the interference being related to the thickness of the layer.

32. A method of manufacturing a semiconductor device, the method comprising:
processing a semiconductor wafer in a plasma chamber;
irradiating a light beam onto a sensor surface located within the plasma chamber;
measuring intensity of light being emitted or reflected by the sensor surface, comparing a value of measured intensity with a threshold value;
determining a time that it is desirable to clean the plasma chamber based on a result of the comparison of the value of measured intensity with the threshold value; and
cleaning the plasma chamber at the determined time.

33. The method of claim 32 wherein processing a semiconductor wafer comprises performing a plasma etching step.

34. The method of claim 32 wherein processing a semiconductor wafer comprises performing a plasma chemical vapor deposition step.
